(19) United States
(12) Patent Application Publication
(10) Pub. No.: US 2011/0110062 A1
(43) Pub. Date: May 12, 2011

(54) Stack-type semiconductor device having chips having different backside structure and electronic apparatus including the same

(75) Inventors: Jae-yong Park, Cheonan-si (KR); Heui-Seog Kim, Asan-si (KR); Jun-young Ko, Cheonan-si (KR); Dae-sang Chan, Asan-si (KR)

(73) Assignee: Samsung Electronics Co., Ltd., Suwon-si (KR)

(21) Appl. No.: 12/661,012

(22) Filed: Mar. 9, 2010

(30) Foreign Application Priority Data
Nov. 6, 2009 (KR) 10-2009-0107088

(51) Int. Cl. H05K 7/02; H01L 23/12

(52) U.S. Cl. 361/783; 257/777; 257/E23.003

(57) ABSTRACT

A stack-type semiconductor device including semiconductor chips having different backside structures and an electronic apparatus including the stack-type semiconductor device include: a base frame for a semiconductor device; a first semiconductor chip that is mounted on the base frame and has a bottom surface having a first surface roughness; and a second semiconductor chip that is mounted on the first semiconductor chip and has a bottom surface having a second surface roughness, wherein the second surface roughness is greater than the first surface roughness by 1.2 nm or more. The stack-type semiconductor device is manufactured to be thin while cracking of the first semiconductor chip is prevented. In addition, changes in data caused by charge loss resulting from diffusion of metal ions, which can occur when a stack-type semiconductor device is a memory device, is prevented.

### CROSS-REFERENCE TO RELATED APPLICATIONS

This application claims the benefit of Korean Patent Application No. 10-2009-0107088, filed on Nov. 6, 2009, in the Korean Intellectual Property Office, the entire contents of which are incorporated herein in their entirety by reference.

### BACKGROUND

The inventive concept relates to a stack-type semiconductor device and an electronic apparatus including the same, and more particularly, to a stack-type semiconductor device including a plurality of stacked semiconductor chips having different bottom surfaces and an electronic apparatus including the same.

Highly integrated semiconductor devices were developed to have increasing degrees of integration in a limited wafer area by reducing a line width of a design rule in a manufacturing process for wafers, and three-dimensionally disposing inner components such as transistors or capacitors. Recently, however, a new aim has been introduced, namely, vertically stacking thin semiconductor chips to mount more semiconductor chips in a single semiconductor package, thereby increasing the degree of integration. Such a method of increasing the degree of integration of a semiconductor device by using techniques of manufacturing semiconductor packages is inexpensive, requires shorter research and development time, and is more likely to be realized, than when the degree of integration is increased in the wafer manufacturing process. Thus, research into the method using techniques of manufacturing semiconductor packages is being actively performed.

Among these semiconductor packages, multichip packages (MCP) including vertically stacked semiconductor chips need thin semiconductor chips to obtain a high degree of integration in a single semiconductor package. However, stacking of thin semiconductor chips may cause various problems.

### SUMMARY

The inventive concept provides a semiconductor device that includes a plurality of thin semiconductor chips stacked without cracks, and is suitable for partial gettering.

The inventive concept also provides an electronic apparatus including a semiconductor device that includes a plurality of thin semiconductor chips stacked without cracks, and is suitable for partial gettering.

According to an aspect of the inventive concept, there is provided a semiconductor device including a plurality of stacked semiconductor chips having different bottom surfaces, wherein the semiconductor device includes: a base frame for a semiconductor device; a first semiconductor chip that is mounted on the base frame and has a bottom surface having a first surface roughness; and a second semiconductor chip that is mounted on the first semiconductor chip and has a bottom surface having a second surface roughness, wherein the second surface roughness is greater than the first surface roughness by 1.2 nm or more.

The base frame may be a lead frame, a printed circuit board (PCB) for a semiconductor package, or a PCB for a semiconductor module. Each of the first and second semiconductor chips may be a flash memory device. The first surface roughness may be in the range of 0.8 nm or less, and the second surface roughness is in the range of 2.0 nm or more.

According to an embodiment of the present inventive concept, the semiconductor device may further include a third semiconductor chip that is mounted under the base frame and has a bottom surface having a third surface roughness, and a fourth semiconductor chip that is mounted under the third semiconductor chip and has a bottom surface having a fourth surface roughness.

The semiconductor device may further an encapsulant for sealing the first semiconductor chip, the second semiconductor chip and a portion of a top surface of the base frame.

The first and second semiconductor chips may have the same thickness.

The first semiconductor chip may be polished, and the second semiconductor chip may be treated by a wheel process.

Each of the first and second semiconductor chips may have a thickness in the range of 20 to 80 μM.

According to another aspect of the inventive concept, there is provided a semiconductor device including: a base frame for a semiconductor device; a first semiconductor chip that is mounted on the base frame and includes a bottom portion that does not have a gettering layer; and a second semiconductor chip that is mounted on the first semiconductor chip and includes a bottom portion having a gettering layer.

According to an embodiment of the present inventive concept, the first and second semiconductor chips are processed differently, and a difference in the surface roughness of the first and second semiconductor chips is 1.2 μm or more.

The first and second semiconductor chips may have the same thickness.

The base frame may be a lead frame, a PCB for a semiconductor package, or a PCB for a semiconductor module.

The first and second semiconductor chips may be flash memory devices.

The semiconductor device may further include a third semiconductor chip that is mounted under the base frame and includes a bottom portion that does not have a gettering layer, and a fourth semiconductor chip that is mounted under the third semiconductor chip and includes a bottom portion that has a gettering layer.

The semiconductor device may further include an encapsulant for sealing the first semiconductor chip, the second semiconductor chip and a portion of a top surface of the base frame.

According to another aspect of the inventive concept, there is provided an electronic apparatus including: an electronic apparatus main body; a PCB for driving an electronic apparatus, wherein the PCB is included in the electronic apparatus main body; and a stack-type semiconductor device mounted on the PCB, wherein the stack-type semiconductor device includes: a base frame for a semiconductor device; a first semiconductor chip that is mounted on the base frame and has a bottom surface having a first surface roughness; and a second semiconductor chip that is mounted on the first semiconductor chip and has a bottom surface having a second surface roughness.

The first surface roughness may be in the range of 0.8 nm or less, and the second surface roughness may be in the range of 2.0 nm or more

### BRIEF DESCRIPTION OF THE DRAWINGS

The foregoing and other features and advantages of the inventive concept will be apparent from the more particular description of preferred embodiments of the inventive concept, as illustrated in the accompanying drawings in which like reference characters refer to the same parts throughout the different views. The drawings are not necessarily to scale, emphasis instead being placed upon illustrating the principles of the inventive concept. In the drawings, the thickness of layers and regions are exaggerated for clarity.

FIG. 1 is a cross-sectional view of a semiconductor chip illustrating gettering using a bottom surface roughness of the semiconductor chip.

FIG. 2 is a cross-sectional view illustrating a stack-type semiconductor device according to an embodiment of the inventive concept.

FIG. 3 is a cross-sectional view illustrating a stack-type semiconductor device according to another embodiment of the inventive concept.

FIG. 4 is a cross-sectional view illustrating a stack-type semiconductor device according to another embodiment of the inventive concept.

FIG. 5 is a block diagram illustrating an electronic apparatus including a stack-type semiconductor device according to an embodiment of the inventive concept.

FIGS. 6A and 6B are sectional views illustrating bottom surfaces of first and second semiconductor chips of the stack-type semiconductor device of FIG. 2.

### DETAILED DESCRIPTION OF THE EMBODIMENTS

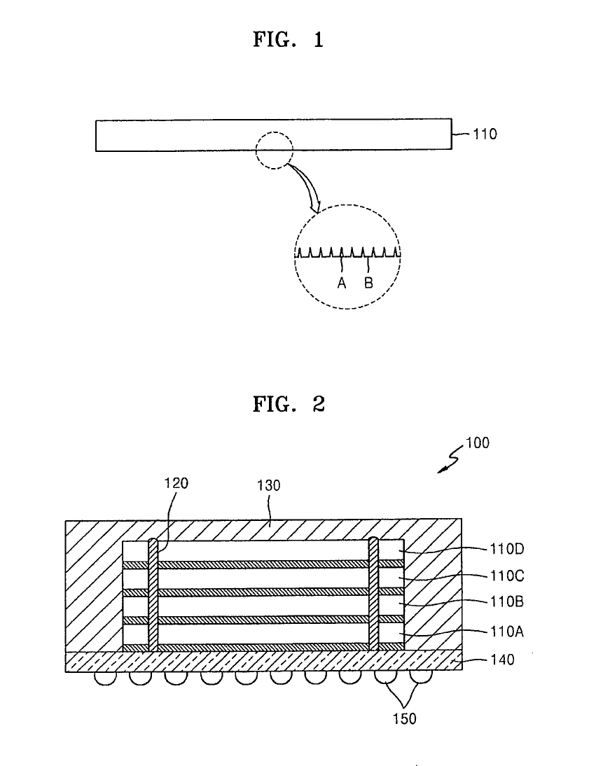

FIG. 1 is a cross-sectional view of a semiconductor chip 110 illustrating gettering by using a bottom surface roughness of the semiconductor chip 110.

Referring to FIG. 1, in general, the semiconductor chip 110 has a flat bottom surface. However, when enlarged, as illustrated in FIG. 1, the bottom surface of the semiconductor chip 110 includes fine grooves A and protrusions B. A structure including the fine grooves A and the protrusions B is formed in a wafer manufacturing process, for example, a wafer back grinding process, and may indicate a surface roughness. In general, the surface roughness of a semiconductor chip is calculated according to the following. Ten or more of fine grooves A and protrusions B included in a bottom surface of a semiconductor chip are selected, and differences in their heights are measured and then an average of the differences is calculated, thereby obtaining the surface roughness of a semiconductor chip.

In processes of manufacturing semiconductor devices, gettering refers to a process of removing metallic contaminants such as heavy metal or alkali metal such as sodium from a semiconductor or an oxide layer. Such metallic contaminants may have been essentially included in a wafer, or may be added thereto in a manufacturing process for a semiconductor device. In general, metallic contaminants have large diffusion coefficients. Thus, when heat treatment is performed thereon, metallic contaminants may diffuse for a very long distance and affect characteristics of a semiconductor device. Examples of a conventional gettering process used in a manufacturing process for a semiconductor chip include phosphorus (P) gettering, surface gettering, and ion implantation gettering.

Surface gettering is a method of removing metallic contaminants by using a surface roughness of a bottom surface of a semiconductor chip, that is, a removing method using the characteristic that ions and charges are easily captured by sharp ends of a subject. In general, it is known that if a surface roughness of a bottom surface of a semiconductor chip is 2.0 nm or more, protrusions of the bottom surface of the semiconductor chip may capture charges and ions and thus may act as a gettering layer.

FIG. 2 is a cross-sectional view illustrating a stack-type semiconductor device 100 according to an embodiment of the inventive concept.

Referring to FIG. 2, the stack-type semiconductor device 100 according to the present embodiment includes a base frame 140 for a semiconductor device, a first semiconductor chip 110A that is mounted on the base frame 140 and has a first surface roughness, and a second semiconductor chip 110B that is mounted on the first semiconductor chip 110A and has a second surface roughness that is greater than the first surface roughness by 1.2 nm or more. In the present embodiment, the base frame 140 may be a printed circuit board (PCB) for a semiconductor package.

In addition, the stack-type semiconductor device 100 may further include third and fourth semiconductor chips 110C and 110D on the second semiconductor chip 110B, and an encapsulant 130, such as an epoxy mold compound (EMC), surrounding a portion of a top surface of the base frame 140 and the first through fourth semiconductor chips 110A, 110B, 110C, and 110D. The base frame 140 may further include solder balls 150, which are attached to a bottom surface of a PCB for a semiconductor package.

The first through fourth semiconductor chips 110A, 110B, 110C, and 110D may be electrically connected to each other and the base frame 140 via a through silicon via (TSV) 120. The TSV 120 may instead be a gold wire or bump. The first through fourth semiconductor chips 110A, 110B, 110C, and 110D may be semiconductor devices in which data written therein may be changed due to loss of charges, for example, flash memory devices.

The first through fourth semiconductor chips 110A, 110B, 110C, and 110D may have the same thickness, for example, in the range of about 20 to 80 μm. However, the thicknesses of the first through fourth semiconductor chips 110A, 110B, 110C, and 110D may not be exactly the same due to process variation in a manufacturing process.

Conventionally, if the first through fourth semiconductor chips 110A, 110B, 110C, and 110D having a thickness in the range of about 20 to 80 μm are vertically stacked to manufacture a semiconductor package or a semiconductor module, the first semiconductor chip 110A contacting the base frame 140 is likely to crack. This is because the base frame 140 may be easily deformed due to different thermal expansion coefficients between the first semiconductor chip 110A and the base frame 140. Thus, the first semiconductor chip 110A being thin may fail to absorb stress due to deformation of the base frame 140 and thus may crack.

The cracking may be prevented using various methods. For example, if the thickness of the first semiconductor chip 110A is greater than those of the semiconductor chips 110B, 110C, and 110D, the cracking may be prevented. Alternatively, if the semiconductor chip 110 is manufactured to have relatively smooth grooves and protrusions, that is, if a semiconductor chip having a bottom surface having a low surface roughness is used, the cracking may be prevented. According to the present embodiment, rigidity of the first semiconductor chip 110A is compensated for by polishing only the first semiconductor chip 110A contacting the base frame 140 until a surface roughness of the first semiconductor chip 110A is 0.8 nm or less, and the other semiconductor chips 110B, 110C, and 110D stacked on the first semiconductor chip 110A are designed to have a surface roughness of 2.0 nm or more.

Thus, the first semiconductor chip 110A and the second through fourth semiconductor chips 110B, 110C, and 110D may have the same thickness of about 20 to 80 μm and bottom surfaces having different surface roughnesses. Thus, since the first semiconductor chip 110A is not manufactured to be thick so as to prevent cracking, the stack-type semiconductor device 100 may be manufactured to be thin.

As illustrated in FIG. 1, if the bottom surface of the first semiconductor chip 110A has a surface roughness of 0.8 nm or less, a gettering layer is not formed in a bottom portion of the first semiconductor chip 110A and thus gettering may not be efficiently performed. In particular, in the case of a non-volatile memory (NVM) such as a flash memory, if gettering is not successfully performed, charge loss may occur in transistors in a semiconductor chip due to copper metal contamination that may occur in a wafer manufacturing process, and thus data written to a semiconductor chip functioning as a memory may be damaged.

The relationship between copper metal contamination and charge loss that may occur in the stack-type semiconductor device 100 is evaluated according to the following.

First, eight semiconductor chips including a flash memory device having a surface roughness of 0.8 nm or less and a thickness of 70 μm are stacked to manufacture a flash semiconductor device Group A sample having a capacity of 16 GB. Also, four semiconductor chips including a flash memory device having a surface roughness of 0.8 nm or less and a thickness of 50 μm are stacked to manufacture a flash semiconductor device Group B sample having a capacity of 64 MB.

Then, data is written to the Group A sample and the Group B sample, and then the Group A sample and the Group B sample are heated three times for one minute in a reflow oven at a temperature of 260° C. in order to activate diffusion of metal ion contaminants in semiconductor chips that do not include a gettering layer. Then, changes in data caused by charge loss in transistors resulting from the diffusion of metal ions contaminants are evaluated. The changes were evaluated using automatic testing equipment (ATE) to perform an electrical function test with regards to data written before the Group A sample and the Group B sample are placed in the reflow oven and the data after the Group A sample and the Group B sample are placed.

The test results are shown in Table 1.

TABLE 1

| | Defect rate (number of defective samples/number of samples | |
|---|---|---|
| Location of semiconductor chip | Group A sample | Group B sample |
| 1 layer | 0%(0/28)** | 0.0%(0/1887)** |
| 2 layer | 36%(10/28) | 0.05%(1/1887) |
| 3 layer | 43%(12/28) | 2.0%(37/1887) |
| 4 layer | 14%(4/28) | 1.3%(25/1887) |
| 5 layer | 50%(14/28) | |
| 6 layer | 18%(5/28) | |
| 7 layer | 61%(17/28) | |
| 8 layer | 75%(21/28) | |

With reference to the test results, it can be seen that even when a semiconductor chip corresponding to a first layer is manufactured to have a surface roughness of 0.8 nm or less, and thus does not include a gettering layer, changes in data caused by charge loss resulting from the diffusion of metal ions contaminants does not occur in the semiconductor chip corresponding to a first layer functioning as a memory. This may be because although a gettering layer is not formed in a bottom portion of the semiconductor chip corresponding to a first layer, the diffusion of metal ions does not cause problems because a semiconductor chip is not disposed between the semiconductor chip corresponding to a first layer and a base frame, which may be a PCB.

Thus, according to embodiments of the present inventive concept, the thickness of the first semiconductor chip 110A may be the same as the thickness of each of the second through fourth semiconductor chips 110B, 110C, and 110D and the thicknesses may be in the range of about 20 to 80 μm, and the first semiconductor chip 110A has a different surface roughness from that of each of the second through fourth semiconductor chips 110B, 110C, and 110D. That is, the first semiconductor chip 110A is manufactured to have a surface roughness of 0.8 nm or less to prevent cracking, while the second through fourth semiconductor chips 110B, 110C, and 110D are each manufactured to have a surface roughness of 2.0 nm or more so as to allow a gettering layer to be formed in bottom portions of the second through fourth semiconductor chips 110B, 110C, and 110D to prevent charge loss caused by diffusion of metal ions. Thus, if a semiconductor device is a flash memory device, change in data written to the semiconductor chip is prevented. Thus, a stack-type semiconductor device having high reliability is obtained.

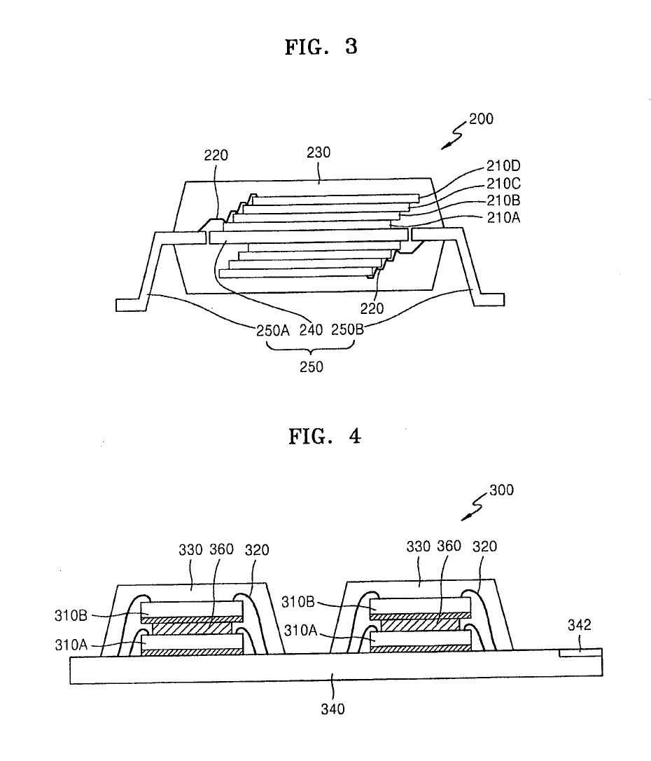

FIG. 3 is a cross-sectional view illustrating a stack-type semiconductor device 200 according to another embodiment of the inventive concept.

Referring to FIG. 3, the stack-type semiconductor device 200 according to the present embodiment is different from the semiconductor chip 100, in that a base frame in the device 200 is a lead frame 250 instead of a PCB for a semiconductor package, and a plurality of semiconductor chips are mounted both on and under the base frame 250. Reference numeral 240 denotes a chip paddle on which a plurality of semiconductor chips 210A, 210B, 210C, and 210D are stacked on and under thereof, and reference numerals 250A and 250B denote outer leads used instead of the solder ball 150 of FIG. 2. In addition, the semiconductor chips 210A, 210B, 210C, and 210D may be connected to the outer leads 250A and 250B of the lead frame 250 by a gold wire 220 instead of the TSV 120.

Thus, by comparing the semiconductor devices of FIGS. 2 and 3, those of ordinary skill in the art can see that the number of semiconductor chips (210A, 210B, 210C, and 210D) and the stack structure thereof may vary, and the connection among the semiconductor chips 210A, 210B, 210C, and 210D and the connection between the semiconductor chips 210A, 210B, 210C, and 210D and the base frame 250 may be variously made using a gold wire or bump or by a TSV. Reference numeral 230 denotes an encapsulant such as an epoxy mold compound (EMC).

Like the previous embodiment, according to the present embodiment, the thickness of the first semiconductor chip 210A may be the same as the thickness of each of the second through fourth semiconductor chips 210B, 210C, and 210D and the thicknesses may be in the range of about 20 to 80 μm, and the first semiconductor chip 210A may have a different surface roughness from that of each of the second through fourth semiconductor chips 210B, 210C, and 210D. That is, the first semiconductor chip 210A is manufactured to have a surface roughness of 0.8 nm or less in order to prevent cracking, while the second through fourth semiconductor chips 210B, 210C, and 210D are each manufactured to have a surface roughness of 2.0 nm or more so as to allow a gettering layer to be formed in bottom portions of the second through fourth semiconductor chips 210B, 210C, and 210D in order to prevent charge loss caused by diffusion of metal ions.

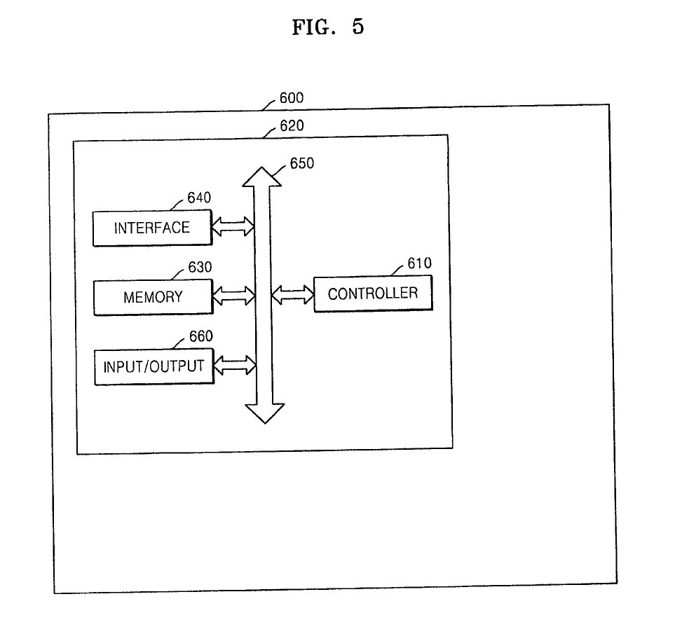

FIG. 4 is a cross-sectional view illustrating a stack-type semiconductor device 300 according to another embodiment of the inventive concept.

Referring to FIG. 4, although the semiconductor devices 100 and 200 according to the previous embodiments have been described with reference to the base frame using the printed circuit board (PCB), the stack-type semiconductor device 300 according to the present embodiment is a semiconductor module.

The semiconductor device 300 may include a base frame 340 for a semiconductor device module, wherein the base frame 340 may be a PCB for a semiconductor module, a first semiconductor chip 310A that is mounted on the base frame 340 and has a bottom portion that does not have a gettering layer, a second semiconductor chip 310B that is mounted on the first semiconductor chip 310A and has a bottom portion that has a gettering layer, and an encapsulant 330, such as an epoxy mold compound (EMC), surrounding a portion of a top surface of the base frame 340 and the first and second semiconductor chips 310A and 310B.

In the stack-type semiconductor device 300, a terminal 342 for outer connection may be formed on an end of the stack-type semiconductor device 300. An interposer 360 may be inserted between the first semiconductor chip 310A and the second semiconductor chip 310B to connect the first and second semiconductor chips 310A and 310B to the base frame 340 with a gold wire 320. Instead of the gold wire 320 or a TSV (see 120 of FIG. 2), a bump may be used to connect the semiconductor chips 310A and 310B or connect the first semiconductor chip 310A to the base frame 340. In addition, instead of the two semiconductor chips 310A and 310B, four through eight semiconductor chips may be stacked, and the stack structure may also be formed under the base frame 340 as illustrated in FIG. 3.

In the stack-type semiconductor device 300, the thickness of the first semiconductor chip 310A may be the same as the thickness of the second semiconductor chip 310B and the thicknesses may be in the range of 20 to 80 μm, and the first semiconductor chip 310A and second semiconductor chip 310B may have different surface roughnesses. That is, the surface roughness of the first semiconductor chip 310A may be manufactured to have a surface roughness of 0.8 nm or less in order to prevent cracking, and the second semiconductor chip 310B may be manufactured to have a surface roughness of 2.0 nm or more so as to allow a gettering layer to be formed in a bottom portion to prevent charge loss caused by diffusion of metal ions.

FIG. 5 is a block diagram illustrating an electronic apparatus 600 including a stack-type semiconductor device according to an embodiment of the inventive concept.

Referring to FIG. 5, the electronic apparatus 600 according to the present embodiment includes an electronic apparatus main body 620, a PCB for driving the electronic apparatus 600, which is included in the electronic apparatus main body 620, and a stack-type semiconductor device 630 that is mounted on the PCB 620 and functions as a memory, wherein the stack-type semiconductor device 630 may include, as illustrated in FIGS. 2 through 4, a first semiconductor chip that is mounted on a base frame and has a bottom surface having a first surface roughness and a second semiconductor chip that is mounted on the first semiconductor chip and has a bottom surface having a second surface roughness that is greater than the first surface roughness by 1.2 nm or more. In this regard, the first surface roughness may be in the range of 0.8 nm or less, and the second surface roughness may be in the range of 2.0 nm or more.

The electronic apparatus 600 may be a mobile system or a system that transmits or receives information. The mobile system may be a personal digital assistant (PDA), a portable computer, a web tablet, a wireless phone, a mobile phone, or a digital music player.

A controller 610 may implement a program and control the electronic apparatus 600. The controller 610 may be, for example, a microprocessor, a digital signal processor, a microcontroller, or an apparatus similar thereto. An input/output apparatus 660 may be used to input data to or output data from the electronic apparatus 600. The electronic apparatus 600 may be connected to an external apparatus, such as a personal computer or a network, via the input/output apparatus 660 and may exchange data with the external apparatus. The input/output apparatus 660 may be, for example, a keypad, a keyboard, or a display. The stack type memory device 630 may store a code, data or code and data that are used to drive the controller 610, or data that has been processed by the controller 610. The memory apparatus 630 may include any one of the semiconductor devices according to the embodiments of the present inventive concept.

An interface 640 may function as a connection through which data may be exchanged between the electronic apparatus 600 and an external apparatus. The controller 610, the input/output apparatus 660, the memory apparatus 630, and the interface 640 may communicate with each other through a bus 650. For example, the electronic apparatus 600 may be a mobile phone, a MP3 player, a navigation device, a portable multimedia player, a portable multimedia player (PMP), a solid state drive (SSD), or any of various household appliances. Selectively, the electronic apparatus 600 may be a desktop computer, a notebook computer, an MP3 player, a PMP, a navigation system, an electronic dictionary, an outer memory apparatus, a mobile phone, a medical appliance, an image reproduction apparatus, a flat display apparatus, a surveillance camera system, or a database server.

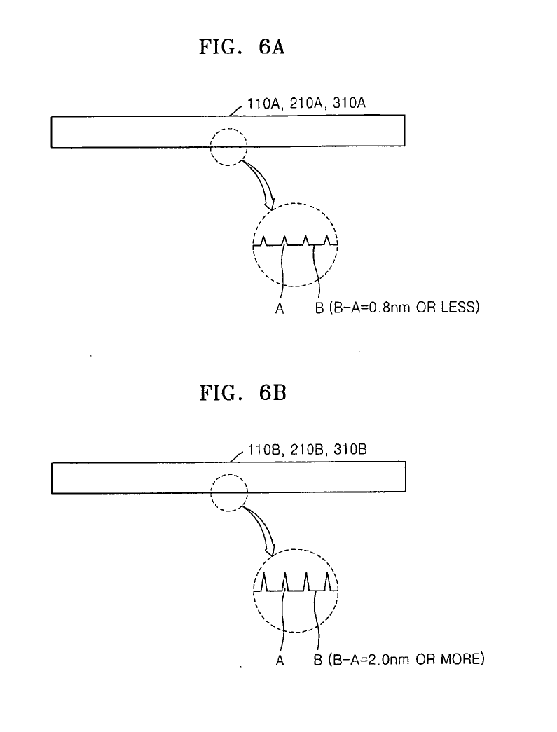

FIGS. 6A and 6B are sectional views illustrating bottom surfaces of the first and second semiconductor chips of the stack-type semiconductor devices of FIGS. 2 through 4.

FIG. 6A illustrates the first semiconductor chips 110A, 210A, and 310A illustrated in FIGS. 2 through 4, respectively, each having a surface roughness of 0.8 nm or less and a bottom portion not having a gettering layer. Since the first semiconductor chips 110A, 210A, and 310A are manufactured to have a bottom surface having a surface roughness of 0.8 nm or less by polishing, a gettering layer is not formed in a bottom portion of each of the first semiconductor chips 110A, 210A, and 310A. However, rigidity of the first semiconductor chips 110A, 210A, and 310A is enhanced.

FIG. 6B illustrates the second semiconductor chips 110B, 210B, and 310B of FIGS. 2 through 4, respectively, each having a surface roughness of 2.0 nm or more and a gettering layer. Since the second semiconductor chips 110B, 210B, and 310B are manufactured to have a bottom surface having a surface roughness of 2.0 nm or more by a wheel process instead of polishing, a gettering layer is formed in a bottom portion of each of the second semiconductor chips 110B, 210B, and 310B, and thus charge loss of a memory device caused by contamination by metal ions may be prevented.

While the inventive concept has been particularly shown and described with reference to exemplary embodiments thereof, it will be understood that various changes in form and details may be made therein without departing from the spirit and scope of the following claims.

What is claimed is:

1. A semiconductor device comprising:
a base frame for a semiconductor device;
a first semiconductor chip that is mounted on the base frame and has a bottom surface having a first surface roughness; and
a second semiconductor chip that is mounted on the first semiconductor chip and has a bottom surface having a second surface roughness,
wherein the second surface roughness is greater than the first surface roughness by 1.2 nm or more.

2. The semiconductor device of claim 1, wherein the base frame is a lead frame, a printed circuit board (PCB) for a semiconductor package, or a PCB for a semiconductor module.

3. The semiconductor device of claim 1, wherein each of the first and second semiconductor chips is a flash memory device.

4. The semiconductor device of claim 1, wherein the first surface roughness is in the range of 0.8 nm or less, and the second surface roughness is in the range of 2.0 nm or more.

5. The semiconductor device of claim 1, further comprising:
a third semiconductor chip that is mounted under the base frame and has a bottom surface having a third surface roughness; and
a fourth semiconductor chip that is mounted under the third semiconductor chip and has a bottom surface having a fourth surface roughness.

6. The semiconductor device of claim 1, wherein the semiconductor device further comprises an encapsulant for sealing the first semiconductor chip, the second semiconductor chip and a portion of a top surface of the base frame.

7. The semiconductor device of claim 1, wherein the first and second semiconductor chips have the same thickness.

8. The semiconductor device of claim 1, wherein the first semiconductor chip is polished.

9. The semiconductor device of claim 1, wherein the second semiconductor chip is treated by a wheel process.

10. The semiconductor device of claim 7, wherein each of the first and second semiconductor chips has a thickness in the range of 20 to 80 μm.

11. A semiconductor device comprising:
a base frame for a semiconductor device;
a first semiconductor chip that is mounted on the base frame and comprises a bottom portion that does not have a gettering layer; and
a second semiconductor chip that is mounted on the first semiconductor chip and comprises a bottom portion having a gettering layer.

12. The semiconductor device of claim 11, wherein the first and second semiconductor chips are processed differently.

13. The semiconductor device of claim 11, wherein the first and second semiconductor chips have the same thickness.

14. The semiconductor device of claim 11, wherein the base frame is a lead frame, a PCB for a semiconductor package, or a PCB for a semiconductor module.

15. The semiconductor device of claim 11, wherein the first and second semiconductor chips are flash memory devices.

16. The semiconductor device of claim 11, wherein a difference in the surface roughness of the first and second semiconductor chips is 1.2 μm or more.

17. The semiconductor device of claim 11, further comprising:
a third semiconductor chip that is mounted under the base frame and comprises a bottom portion that does not have a gettering layer; and
a fourth semiconductor chip that is mounted under the third semiconductor chip and comprises a bottom portion that has a gettering layer.

18. The semiconductor device of claim 11, wherein the semiconductor device further comprises an encapsulant for sealing the first semiconductor chip, the second semiconductor chip and a portion of a top surface of the base frame.

19. An electronic apparatus comprising:
an electronic apparatus main body;
a PCB for driving an electronic apparatus, wherein the PCB is included in the electronic apparatus main body; and
a stack-type semiconductor device mounted on the PCB,
wherein the stack-type semiconductor device comprises:
a base frame for a semiconductor device;
a first semiconductor chip that is mounted on the base frame and has a bottom surface having a first surface roughness; and
a second semiconductor chip that is mounted on the first semiconductor chip and has a bottom surface having a second surface roughness.

20. The electronic apparatus of claim 19, wherein the first surface roughness is in the range of 0.8 nm or less, and the second surface roughness is in the range of 2.0 nm or more.
